(19) United States
(12) Patent Application Publication
(10) Pub. No.: US 2024/0377471 A1
(43) Pub. Date: Nov. 14, 2024

(54) BATTERY MEASURING SYSTEM

(71) Applicant: HEIMDALYTICS GMBH, Kiel (DE)

(72) Inventors: Christoph Weber, Kiel (DE); Clemens Van Zeyl, Oakville (CA)

(21) Appl. No.: 18/692,596

(22) PCT Filed: Sep. 16, 2022
(86) PCT No.: PCT/EP2022/075813

§ 371 Date: Mar. 15, 2024

(30) Foreign Application Priority Data
Sep. 16, 2021 (DE) 10 2021 210 298.0

(51) Int. Cl. G01R 31/396; G01R 31/367; G01R 31/388; G01R 31/392; H01M 10/42

(52) U.S. Cl. CPC G01R 31/396; G01R 31/367; G01R 31/388; G01R 31/392; H01M 10/4285

(57) ABSTRACT

The invention relates to a battery cell measuring unit which is configured to detect measured variables of a battery cell unit in a cell string of a battery. The measuring unit is furthermore configured to detect measured variables for determining a state of the battery cell unit during operation of the battery and to provide the determined measured variables as a set of measurement data to a battery control unit.

### TECHNICAL FIELD

The invention relates to a battery cell measurement unit, a measurement unit arrangement, a battery measurement system, a use of the battery measurement system, an electrically powered means of transportation, a stationary storage device, e.g. for grid frequency regulation or a microgrid storage device, and a method for providing a measurement data set of a battery cell unit in a cell string of a battery for determining a state of the battery cell unit.

### STATE OF THE ART

The condition of batteries, e.g. batteries in a means of transportation or in a stationary storage unit, is usually determined by monitoring cell voltages, —currents and—temperatures. This method is often inaccurate as it does not take into account the complex behavior of the battery. Furthermore, age-related changes are not taken into account. In order to obtain a highly accurate condition measurement, the battery can be removed and placed in a measuring stand. An impedance spectrum of the entire battery can then be determined and compared with reference values. This procedure is complicated and expensive and is therefore carried out relatively rarely. This also means, for example, that the current status is not always available and the expected service life is not sufficiently known. This can lead to dangerous situations, which is why batteries must be replaced at regular intervals and replacement batteries must be kept in stock.

### DISCLOSURE OF THE INVENTION

An object of the invention could therefore be to provide an improved system for determining the condition of a battery.

The object is solved by the subject-matter of the independent patent claims. Advantageous embodiments are the subject of the dependent claims, the following description and the figures.

The described embodiments similarly relate to the battery cell measurement unit, the measurement unit assembly, the battery measurement system, the use of the battery measurement system, the electrically powered transportation means, the stationary storage device, and the method of providing a measurement data set of a battery cell unit in a cell string of a battery for determining a state of the battery cell unit. Synergy effects may result from various combinations of the embodiments, although they may not be described in detail.

Further, it should be noted that all embodiments of the present invention relating to a method may be carried out in the described order of steps, but this need not be the sole and essential order of steps of the method. The methods disclosed herein may be carried out with a different sequence of the disclosed steps without departing from the particular method embodiment, unless expressly stated otherwise below.

According to a first aspect, a battery cell measuring unit is provided. The measuring unit is configured to detect measured variables of a battery cell unit in a cell string of a battery. The measuring unit is furthermore configured to detect measured variables for determining a state of the battery cell unit during operation of the battery and to provide the determined measured variables as a measurement data set to a battery control unit.

This provides a measuring unit that detects, for example, physical or chemical measured variables that are suitable for describing a state of the battery or environmental conditions of the battery. An essential feature of the measuring unit is that it is configured to record the measured variables during the intended operation of the battery. This can be, for example, in the case of a means of transportation while driving or flying. It should be noted that the measuring unit does not detect the state of the battery system as a whole, but only the state of a battery cell unit. It is also possible to detect the status of several cell units simultaneously. This means that a key point here is that those cell units for which no measurement is currently being taken are still operational, so that the battery system is or can be in use by these cell units even during the measurement. The battery cell units that are being measured, on the other hand, are briefly disconnected from operation during the measurement, so that an exact measurement can be carried out without, for example, an outflow of measurement currents or interference, as described in more detail in the following embodiments.

A state is, for example, a state of charge or a “state of health”, or a physical or chemical property that can change through the use of the battery or generally over time. A battery cell unit is the smallest unit that can be measured “from the outside” in terms of voltage, i.e. the unit of cells that makes a common plus and minus pole accessible and thus represents the overall potential of the unit. As a rule, these are battery cells connected in parallel or in series. A battery cell unit can therefore have one energy storage element or several energy storage elements arranged in parallel or in series. The structure of the battery with battery cell units and cell strings is described below.

In addition to the measured variables, the measurement data set can also contain other values that the measuring unit calculates from the measured variables, e.g. impedance values. The measurement data set does not necessarily contain all measured values.

The measured variables determined are provided to a battery control unit as a measurement data set. The battery control unit controls the measurement, for example, and can evaluate the measurement data, as explained further below.

According to one embodiment, the measuring unit is furthermore configured to detect the following measured variables: An alternating current injected into the battery cell unit with different frequencies as excitation for a determination of an impedance spectrum, and a voltage and a phase relative to the injected alternating current as voltage response for the determination of the impedance spectrum. The measuring unit is also configured to provide values of the measured variables and/or values of the impedance spectrum with a time stamp and to make them available to the battery control unit as a measurement data set.

The impedance spectrum can be determined by the measuring unit, which sends the determined or calculated values of the impedance spectrum to the battery control unit, or the measuring unit sends the raw data to the battery control unit, which then determines values of the impedance spectrum from the received raw data.

The impedance spectrum shows the impedance of the battery cell unit as a function of the frequency. The impedance can be displayed as a magnitude and phase or as a real and imaginary part. The frequency range is, for example, between a few millihertz and a few kilohertz. A sinusoidal (also multisinusoidal) current excitation with an integer period is injected into each cell unit and the voltage response is measured using a four-point measurement, for example. The complex frequency spectrum of the impedance is obtained by Fourier transformation according to magnitude and phase (or also real and imaginary partial value). The alternating current and the voltage response for impedance spectroscopy are recorded by the measuring unit for the individual battery cell unit.

According to an embodiment, the measuring unit is also configured to additionally record one or more of the following measured variables: Temperature, pressure in the battery cell unit, chemical and physical parameters.

The overall state of the battery cell unit may thus be inferred from the individual physical and chemical states, which can influence, for example, a state of charge, a “health” state and/or the service life of the battery.

The measuring unit may also be configured to provide the measurement data set to the battery control unit wirelessly, e.g. in accordance with a short-range radio standard, or wired, e.g. via Ethernet or a CAN bus.

According to a further aspect, there is provided a measuring unit arrangement comprising a plurality of measuring units described herein for a plurality of battery cell units in the battery. The battery has a DC bus connection with a plurality of cell strings arranged in parallel at this DC bus connection, each cell string having one or more battery cell units connected in series. At least some of the cell strings each have one or more measuring units, each of which records measured variables of a battery cell unit. The one or more measuring units are configured to simultaneously record measured variables of battery cell units of the cell string and to organize the recorded measured variables for provision to the battery control unit as a measurement data set.

The battery cell units can be a single cell or organized as series and/or parallel connected cells forming cell modules.

The number of measuring units can correspond to the number of battery cell units so that, for example, one measuring unit is assigned to each battery cell unit. However, it would also be possible for several battery cell units of a cell string to be assigned to one measuring unit. Preferably, all battery cell units of a cell string are measured simultaneously. This is significant in that it allows measurements to be carried out, for example, switchably per cell string, as described in more detail below, which shortens the measurement time. It should be noted here that in this disclosure, a battery cell unit may include a plurality of cells, which are also referred to herein as energy storage elements. That is, a measurement unit injects current and measures values for a battery cell unit with multiple, e.g. 14, cells or energy storage elements. The energy storage elements are not further distinguished in this disclosure.

The cell strings terminate at one of their ends at a DC busbar connection, which can be realized, for example, by a busbar or cable connection, at which the battery voltage or the current from all connected cell strings is available or made available.

The measurement data can, for example, be organized as a measurement data set, which can contain several measurement variables and time parameters, for example, which the measurement units transmit to the battery control unit.

According to a further aspect, a battery measurement system is provided, which has a measurement unit arrangement described herein with a plurality of measurement units arranged in at least one cell string, as well as a battery control unit and a current source for each measurement unit, which can also operate as a sink. Each of the measuring units is assigned to at least one battery cell unit, and each of the measuring units is configured to send measurement data records to the battery control unit. The battery control unit is configured to receive measurement data records from measurement units of at least one cell string. The current sources are each configured to inject a current with a frequency into the battery cell unit of the associated measuring unit.

In other words, each measuring unit is assigned a current source that injects a current into those battery cell units that are assigned to the measuring unit. The current has a frequency. The fact that the current has a frequency is to be understood here as meaning that it has at least one frequency or that it represents a superposition or sequence of currents with different frequencies. The different frequencies can occur simultaneously or one after the other. The current source can operate as a source and as a sink. From this, the current can be modulated e.g. sinusoidally, i.e. with positive and negative amplitude as excitation.

The battery control unit is also equipped with logic that allows diagnostic functions to be executed. The diagnostic functions are based on a model of a machine learning process. The battery control unit receives the model or the values of the model parameters via a wireless interface, or alternatively via a wired interface from a computing unit, as described in more detail below. The logic may include hardware and/or software elements. It is understood that the battery control unit can have hardware such as processors, logic modules, program memories and registers, clock modules, etc., depending on its tasks. The diagnostic functions relate in particular to characteristics of the interior of the battery, current statistics, etc. Examples of diagnostic functions are the current state of charge (SoC), the state of health (SoH), the temperature of the cell core or even a default (recommended) value for the upcoming maximum power output/input of the battery system to protect it and extend its service life. The model does not necessarily have to provide all the diagnostic functions mentioned or provided. For example, the cell temperature can still be recorded directly by a temperature sensor.

According to an embodiment, each cell string has a switch or a switchable transducer to separate the cell string from the other cell strings, whereby only those measurement units that are assigned to this cell string provide measurement variables and measurement data records.

In this way, the cell string in which measurements are made can be disconnected or decoupled from the DC bus connection and thus, for example, from the load, consumer or an energy source and from other cell strings. The disconnection can be made galvanically by a switch, e.g. a relay or a semiconductor, e.g. a transistor in a converter, or by switching an impedance of the converter so that the cell string is only connected to the busbar with high impedance.

The term “converter” is synonymous with the term “converter”. Examples of converters are DC/DC converters or DC/AC or AC/DC converters, where “DC” stands for direct current and “AC” for alternating current.

In other words, preferably only the battery cell units of one cell string or the battery cell units of a selection of cell strings are measured at any one time. The other cell strings are isolated from this cell string with high impedance or alternatively galvanically. In this way, the current injected by the source/sink can flow completely into the cells connected to the measuring units of the string and interference from other cell strings can be avoided. For example, the cell strings can be “activated” in rotation for a measurement or disconnected from the DC bus connection.

Due to the isolation resulting from the high impedances of the converters, cell strings can alternatively be measured in parallel without the cell strings influencing each other. Furthermore, a bidirectional converter can be used so that the separated string can be reconnected to the DC bus connection at any time, regardless of the state of charge of the string.

According to an embodiment, the battery control unit is configured to generate a feature data set from the measurement data sets of the measurement units, to apply a time stamp to the feature data set and to temporarily store the feature data set including the time stamp.

In addition to the time stamp, the characteristic data set can contain, for example, impedance values at frequency support points, as well as current and voltage values, statistical information on measured current and voltage ranges, an SoC, calculated by means of a current integration over the time interval between the last measurement and the current measurement, a temperature, etc.

The battery measurement system has a local memory for storing the characteristic data records. Furthermore, the battery measurement system can have sensors for measuring the temperature of a battery cell unit or other sensors that record environmental parameters such as temperature, humidity, mechanical stress, etc. of the environment.

According to a further embodiment, the battery measurement system has a computing unit and a communication interface, which can be, for example, a local or wired interface, such as Ethernet, or a wireless interface, such as WiFi, Bluetooth, LTE, 5G, radio, cloud, which are configured to transmit the cached feature data records to the computing unit, e.g. a server, whereby the computing unit is configured to receive the temporarily stored feature data records and to calculate a model of a machine learning system cyclically or dynamically on the basis of current feature data records, whereby the model provides diagnostic functions for each measuring unit, and the computing unit is also configured to transmit the model to the battery control unit via the communication interface.

The computing unit, e.g. a cloud computer, server or controller, stores all characteristic data records with a time stamp in a database. This creates a digital life/health record that can be used to seamlessly monitor the most important features of the battery system. Even at this stage of the data situation, anomalies in the battery system can be detected at cell unit level through simple checks of range limits. The cloud computer also makes it possible to train updated models using machine learning methods on the basis of the latest feature data sets (e.g. from the last 6 months).

This means that the calculation unit regularly trains the model and sends the resulting model back to the battery control unit. The battery control unit then feeds the current characteristic data records into the model. This allows the battery control unit to provide important diagnostic functions that are periodically updated. Examples of diagnostic functions are the current state of charge (SoC), the state of health (SoH), the temperature of the cell core or even a default (recommended) value for the upcoming maximum power output/input of the battery system to protect it and extend its service life. The model does not necessarily have to provide all the diagnostic functions mentioned or provided.

In the event that the battery control unit has sufficient computing capacity and memory space, in particular to store the history of the battery cell units, the function of the computing unit can be taken over by the battery control unit. The communication interfaces and units are not required in this case.

According to an embodiment, the battery measurement system is configured to disconnect the disconnected cell string for a short time for measurement while the other cell strings continue to work according to regular operation of the battery.

This means that the cell string to be measured is switched off for a short time for measurement, while the other strings can continue to work for regular operation of the battery instead of having to carry out the measurement after a long relaxation time of hours. In this context, “regular operation” refers to the operation of the cell in accordance with its intended purpose, as opposed to measurement operation. Regular operation can include a withdrawal or supply of current, or even a rest phase.

According to one embodiment, the battery measurement system also has sensors that are configured to detect other environmental parameters, such as physical and chemical parameters, and a local memory which is configured to store the feature data records and the other measured environmental variables recorded.

Other measured environmental variables include ambient temperature, humidity, etc.

According to an embodiment, the model is a model according to a recurrent (encoder/decoder) neural network method of known or future type, a reinforcement learning method such as Distributed Distributional/Deep Deterministic Policy Grading (D4DPG/DDPG) method and/or an actor/critic method, wherein the reinforcement learning method uses a reward for learning within an environment model.

According to an embodiment, the model is an artificial intelligence model (e.g. of a neural network) that is configured to generate each time stamp from the feature data sets using the time stamps.

This embodiment describes the reward function for learning the SoC diagnostic model. The agent of the neural network continuously estimates the future diagnostic value SoC between 0 . . . 100%. A difference value ΔSoC can also be estimated between directly adjacent timestamps. ΔSoC can therefore assume values between-100% and 100%. This ΔSoC value is also available in the coulomb counter of the battery control unit (integration of the current value) as a measured variable as a very precise variable. The comparison between the estimated ΔSoC and the measured ΔSoC values can be used in the environment model to evaluate/reward the “absolute SoC” diagnostic variable to be estimated. Since the SoC is technically limited between 0 . . . 100%, the learning procedure continuously improves not only the estimation of the ΔSoC, but also (indirectly) the estimation of the absolute SoC.

According to an embodiment, the model is an artificial intelligence model that is further configured to estimate a SoC state value, a SoH state value, a state value with respect to a temperature, a chemical property and/or a physical property.

Artificial intelligence is also understood here as neural networks or machine learning.

In a variant, learning may also be supported by a simulation. Here, for example, software running on a PC or laptop runs through a predefined, typical performance profile, e.g. of a forklift truck or other means of transportation. The power unit has drivers that represent a power source and provide a charging current, or units that represent a load and absorb the battery current. As already described, the measurement data is sent to the computing unit in order to calculate the model or the values for the parameters of the model. After the learning phase, the model can be transferred to the battery control unit and used for real operation, e.g. of the means of transportation, and thus for continuous monitoring of the battery during operation.

According to a further aspect, a method for providing a measurement data set of a battery cell unit of a cell string of a battery for determining a state of the battery cell unit is provided, comprising the following steps:
Recording of measured variables of the battery cell unit during operation of the battery;
Providing the recorded measured variables as measurement data for a battery control unit to determine the status of the battery cell unit using a previously trained artificial intelligence model.

According to a further aspect, a use of a battery measurement system presented herein is provided in an electrically powered means of transportation, a stationary storage of electrical energy, for example for grid frequency regulation or in a microgrid.

The term means of transportation is understood here to include motor vehicles, trains, boats and ships, airplanes, helicopters and the like.

According to a further aspect, an electrically powered means of transportation or a stationary storage device for electrical energy is provided, which has a battery measurement system as described herein.

It can therefore be said that the generated models “live” and evolve with the individual operation of the battery system. The model generation is therefore run during operation and independent of the cell chemistry used and the installation situation as well as the cabling properties and therefore independent of the contact resistances. Anomalies can be detected quickly and reliably by the model and the diagnostic functions in the battery control unit. This can be done, for example, by simple checks of range limits in the battery system at cell unit level. Furthermore, an individual digital life and/or health record can be created and maintained for each battery, with which the most important characteristics of the battery system can be monitored seamlessly, for example by the computer unit storing the characteristic data records with time stamps in a database accordingly.

The method may be carried out, at least in part, by a computer program element which is executed on one or more processors. The computer program element may be part of a computer program, but it may also be an entire program in itself. For example, the computer program element may be used to update an existing computer program to arrive at the present invention.

The computer-readable medium can be regarded as a storage medium, such as a USB stick, a CD, a DVD, a data storage device, a hard disk or any other medium on which a program element as described above can be stored.

Other variations of the disclosed embodiments may be understood and carried out by one skilled in the art in practicing the claimed invention by studying the drawings, the disclosure and the appended claims. In the claims, the word “comprising” does not exclude other elements or steps, and the indefinite article “a” or “an” does not exclude a plurality. A single processor or other unit may perform the functions of multiple items or steps recited in the claims. The mere fact that certain actions are recited in interdependent claims does not mean that a combination of those actions cannot be used advantageously. A computer program may be stored/distributed on a suitable medium such as an optical storage medium or a semiconductor medium supplied together with or as part of other hardware, but may also be distributed in other forms, for example via the Internet or other wired or wireless telecommunication systems. Reference signs in the claims should not be construed to limit the scope of the claims.

### BRIEF DESCRIPTION OF THE DRAWINGS

In the following, embodiments of the invention are explained in more detail with reference to the schematic drawings.

FIG. 1 shows a general overview of a battery measurement system,

FIG. 2 shows a block diagram of a battery system,

FIG. 3 shows a simplified circuit diagram for a battery system,

FIG. 4 shows a diagram of impedance spectra of a battery cell unit at different points in time,

FIG. 5 shows a diagram of impedance spectra at different times and different battery cell units,

FIG. 6 shows a diagram of a measuring circuit in a measuring unit,

FIG. 7 shows a block diagram of an artificial intelligence,

FIG. 8 shows a flow chart of a method for providing a measurement data set of a battery cell unit,

FIG. 9 shows a table with an example of a feature data set,

FIG. 10 shows a table with an example and an explanation of a calculation rule for evaluating the “estimation quality” of a selected feature data set,

FIG. 11 shows a block diagram with a test arrangement of the battery measurement system,

FIG. 12 shows an illustrated structure diagram for direct measurement of the SoH,

FIG. 13 shows an illustrated structure diagram for estimating the SoH.

Corresponding parts are marked with the same reference signs in all figures.

### EMBODIMENTS

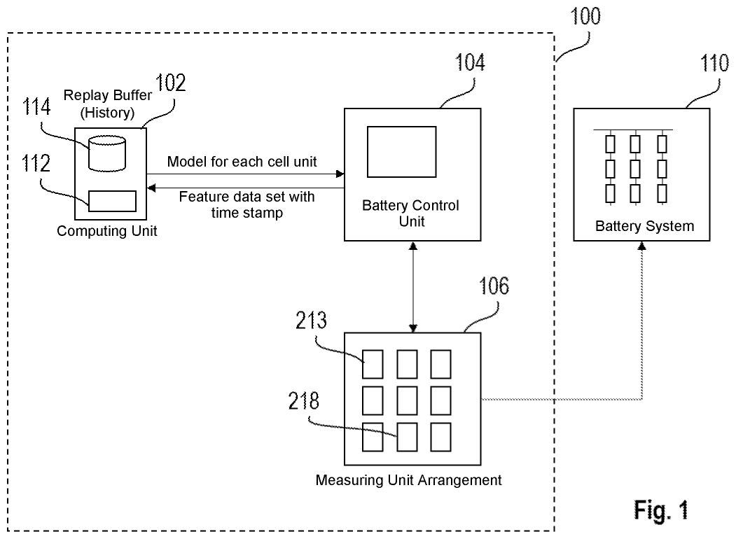

FIG. 1 shows a block diagram with a general overview of a battery measuring system 100, which has a battery control unit 104, a measuring unit arrangement 106 with measuring units, which are exemplarily provided with reference signs 213 and 218 in FIG. 1, and a computing unit 102. The aforementioned components can be individual devices or integrated into a housing. The data connections can be wireless and/or wired.

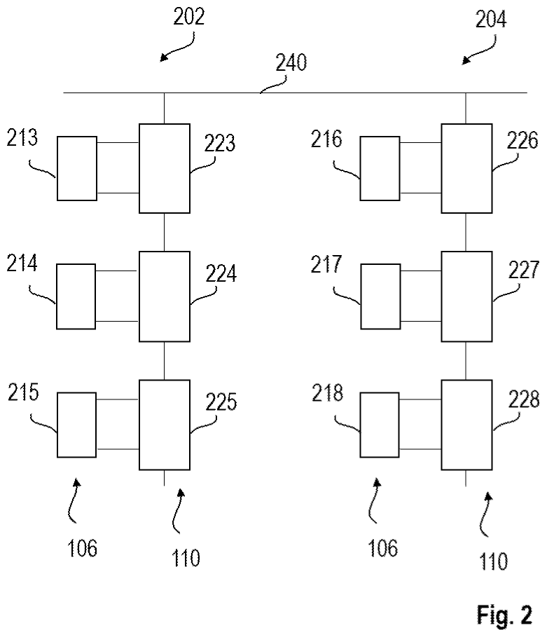

As shown in FIG. 2, each of the battery cell measurement units 213 . . . 218 of the measurement unit arrangement 106 is connected to a battery cell unit 223 . . . 228. The cell strings 202 and 204 with the battery cell units 223 . . . 225 and 226 . . . 228 respectively are each connected at one of their ends to the DC bus connection 240, which is connected to a load or consumer or a power generator (not shown).

Each of the battery cell measuring units 213 . . . 218 records measured variables such as current and voltage of the associated battery cell unit 223 . . . 228 of a cell string 202, 204 of a battery during its operation. They can thus detect the status of the battery cell units. The condition of the battery system 110 can thus be estimated by the entire arrangement 106. The measuring units 213 . . . 218 provide the determined measured variables as a characteristic data set with a time stamp to the battery control unit 104 shown in FIG. 1. The storage volume of the battery control unit 104 is sufficiently large so that all the measurement data obtained can also be temporarily stored for several days. The battery control unit 104 controls the measurements and evaluates them, whereby it sends the measurement data to the computing unit 102 for the evaluation or parts of the evaluation. To send the data and control signals between the measuring unit arrangement 106 and the battery control unit 104 or the battery control unit 104 and the computing unit 102, the components 102, 104, 106 involved have wireless or wired communication units and interfaces. For example, the battery control unit 104 has a common wireless interface such as WiFi, Bluetooth, LTE, 5G, etc.

The computing unit 102 is, for example, a cloud computer with high computing power and has, in addition to one or more processing units 112 or controllers 112, a memory 114 in which both the current feature data sets and previous feature data sets are stored. The processing unit 102 further houses artificial intelligence such as a neural network. The computing unit trains the neural network to obtain a current diagnostic model for each cell unit. The battery control unit 104 cyclically receives the current diagnostic model for each cell unit from the cloud computer 102 via the wireless interface, which can provide important diagnostic functions such as the current state of charge (SoC), the state of health, the temperature of the cell core or also a default value for the upcoming maximum power output/input of the battery system for conservation and service life extension on the central battery control unit 104 on the basis of current characteristic data sets.

The battery control unit 104 receives feature data sets from measurement units 213 . . . 218 of at least one cell string 202, 204. A cell string 202, 204 may comprise one or more battery cell units. In turn, a battery cell unit may be a single cell or a plurality of cells connected in parallel or in series, so that the battery cell unit forms a module. Preferably, the battery cell units 223 . . . 225 of a cell string 202 are measured simultaneously during a first time period and the battery cell units 226 . . . 228 of a cell string 204 are measured simultaneously during a second time period different from the first time period. This avoids mutual interference in the cell strings 202, 204. Depending on the capacity, in particular the memory and computing capacity of the battery control unit 104 and/or the computing unit 102, first a part of the battery cell units 223 . . . 225 can be measured within a string and then another part.

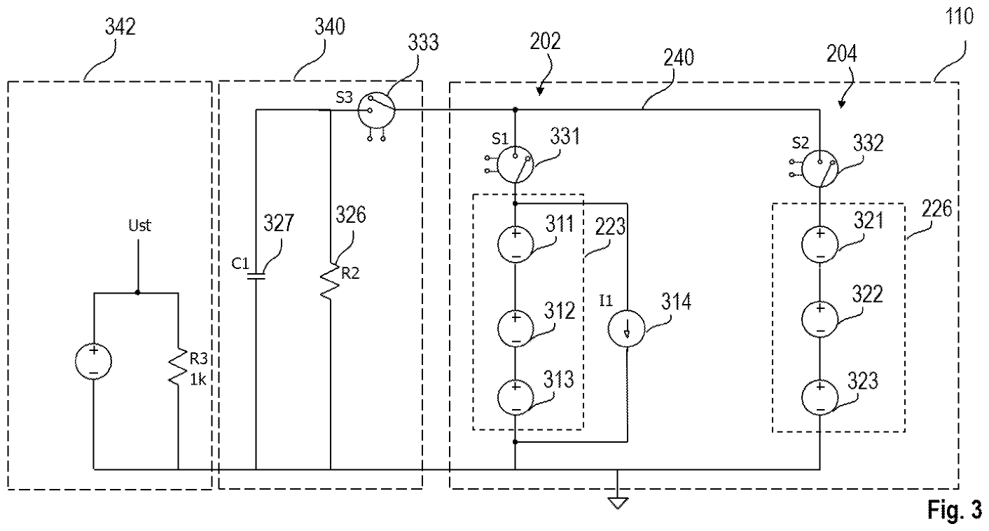

FIG. 3 shows a simplified circuit diagram showing a battery system 110 comprising two strings 202, 204 each with a battery cell unit 223, 226, which in turn each comprise three energy storage elements or cells 311, 312, 313 or 321, 322, 323 connected in series.

This decoupling can be carried out, for example, by a switch such as a simple relay.

Switches 331 and 332 are shown in FIG. 3, which can perform such decoupling for each line. Electronic solutions, such as transistors, can also be used here. FIG. 3 also shows a main contactor 333, which can be used to disconnect the operated loads/generators 340 from the cell strings 202, 204 during the measurement, as well as a controlled voltage source 342 to represent a variable standby current.

In a special embodiment, the cell strings 202, 204 each have their own DC/DC converter at the positive end, for example. This is the case in large stationary storage systems, for example. These DC/DC converters actually ensure that the voltage levels between the strings can be balanced in a “controlled” manner. They can be used and switched in such a way that they act as a “relay” 331 and 332, which separates the string to be measured from the other strings with a high impedance. For example, this can be a DC/DC resonance converter so that the impedance can be controlled via the switching frequency, or a converter that can be used as a switch.

The source/sink I1 314 is part of the battery measurement unit 213, which in this example can simultaneously spectroscope the three energy storage elements 311, 312, 313 in series of the first string 202.

The number of battery measuring units required per string is (N DIV K)+1, where N is the number of energy storage elements per string, DIV is an integer division and K is the maximum number of energy storage elements on which the voltages, temperatures and the current from I1 314, and thus the impedance spectrum, can be measured per measuring unit 213 . . . 218.

Example: N=30 energy storage elements per string; K=12 measuring inputs in the measuring unit, so that (30 DIV 12)+1=3 measuring units.

The resistance R2 326 and the capacitance C1 327 symbolize a possible load of the battery, which must be supplied by the unmeasured string 204 during the impedance measurement of the string 202. Impedances can only be meaningfully measured by the battery measuring units when the cell units to be measured are at “rest”, i.e. almost no current is flowing into or out of the cell units to be measured. These “rest phases” occur in many battery systems during normal operation with regard to the entire battery:
1) An electric car is parked or stopped at traffic lights.
2) A forklift truck is briefly left by the driver so that he can carry out a picking task.
3) A stationary storage system currently consumes or releases almost no electrical power if the disconnection/disconnection of a string ensures the continued operation of the battery system.

In other stationary systems, such as frequency regulation, microgrids, etc., where a constant current, possibly even a constant current flow, must be maintained, a single string can be isolated for the measurement, as already described, which then has no current inflow or outflow during the measurement. The other cell strings can then be used to maintain a small current. In this case, the strings can be measured in sequence. In the event of sudden large power requirements that exceed a threshold value, the measurement of the impedance spectrum can be interrupted immediately and the string can be reconnected to the entire battery system via the assigned switch, e.g. 331 or 332. This prevents all strings from maintaining an almost identical state of charge even after the measurement.

The source/sink I1 314 can be operated with a single sinusoidal excitation with, for example, a frequency of 10 Hz, or with several sinusoidal currents of the same amplitude that have different frequencies, for example in the range of 25 mHz . . . 1.5 kHz. The measurement time can be shortened by simultaneously impressing several currents. For example, the impedance per frequency decade is measured simultaneously at the following interpolation points: f₁=25 mHz, f₂=50 mHz, f₃=75 mHz, f₄=125 mHz and f₅=200 mHz. The sinusoidal excitation then follows according to the following series function:

$${I}_{excitation} = {I}_{ampl} [ sin ( {ω}_{1} t + {φ}_{1} ) + sin ( {ω}_{2} t + {φ}_{2} ) + … + sin ( {ω}_{5} t + {φ}_{5} ) ] ,$$

where ωi=2fπi

A Fourier analysis can be carried out to evaluate the current and/or voltage measurements for the impedance spectrum. The Fourier analysis can be carried out in the battery control unit, for example, or already in the respective measuring units 213 . . . 218. For the digital Fourier analysis, it is advantageous if ω₂ . . . ω₅ are multiples of ω₁ in each case. φ₁, . . . , φ₅ can then be optimized offline so that the overall amplitude of the lexcitation is as small as possible when the individual current components are superimposed. This ensures that the small signal properties are fulfilled during the measurement. For example, it can be mathematically proven that with an optimized selection of φ₁, . . . , φ₅ a total maximum amplitude of 2.3*Iₐₘₚₗ is not exceeded. Without an optimized choice of φ₁, . . . , φ₅, the total amplitude could be a maximum of 5*Iₐₘₚₗ in the worst case.

By selecting specific frequency reference points, the impedance can be evaluated with high precision using the fast Fourier transformation (FFT) on the digital path. DC components or “interference frequencies” can be easily filtered out of the measured spectrum of the current and cell voltages.

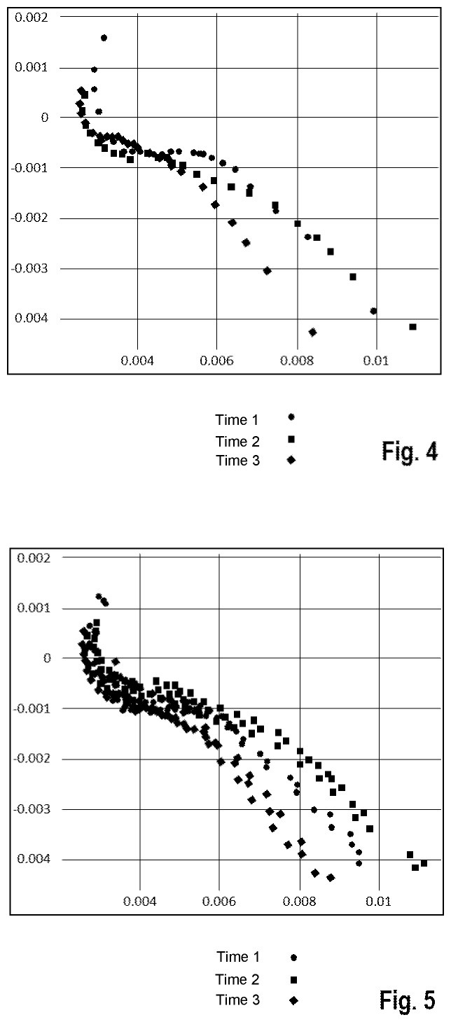

FIG. 4 shows an example diagram of impedance spectra of a battery cell unit calculated in the battery control unit with real part (x-axis) and imaginary part (y-axis) of the impedance Z in ohms, according to the current and voltage values recorded by a measuring unit. Each measuring point (frequency support point) represents the impedance for a frequency that corresponds to the frequency of the injected current. The spectrum represents the impedance spectra for three different points in time “Time 1”, “Time 2”, “Time 3”, which are characterized in FIG. 4 by different geometric shapes of the measuring points. The spectrum can be used to draw conclusions about the state of health and state of charge of the battery cell unit, for example by comparing it with reference curves. Another possibility for estimating the state of health and the state of charge is the use of artificial intelligence, for example using neural networks, as described herein.

FIG. 5 shows an example diagram with impedance spectra of several battery cell units or cells of a string, which are accordingly based on the measurement of several measuring units. Here, too, the spectra are shown at three different times “Time 1”, “Time 2” and “Time 3”, which can be distinguished by the different geometric shapes of the measurement points. It can be seen that the “curves” of the different battery cell units behave similarly at one point in time, whereas the behavior at different points in time differs significantly.

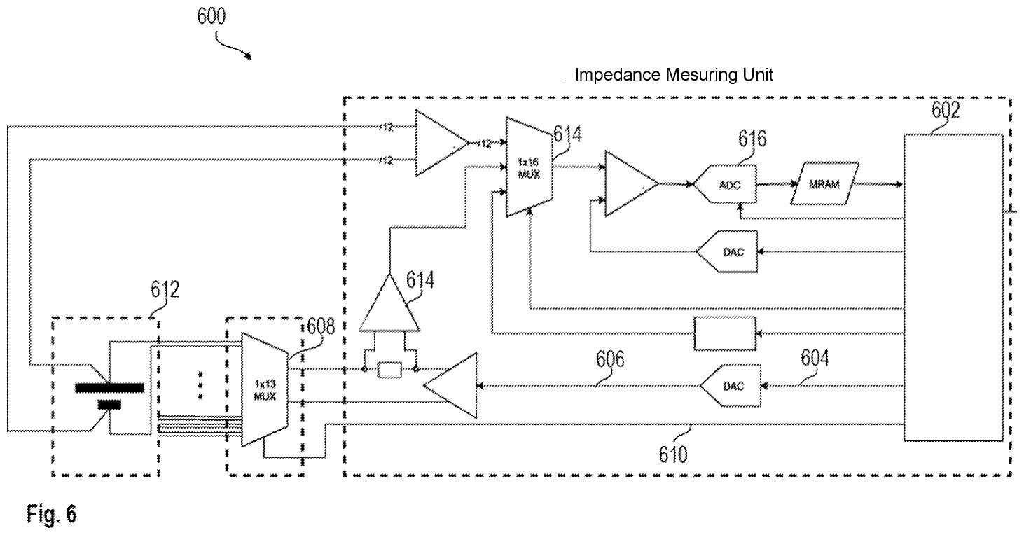

FIG. 6 shows a simplified diagram of a measuring circuit 600 of a measuring unit 213 . . . 218. The measurement is controlled by a microprocessor 602. The microprocessor 602 outputs superimposed signals 604 of different frequencies, which are analog-converted 606 and sent to a multiplexer 608 as superimposed sinusoidal currents. The microprocessor 602 uses the channel signal 610 to select the cell or battery cell unit to be measured, into which the superimposed sinusoidal currents are injected, and whose voltage is recorded in response to the currents with a 4-point measurement 612 and is passed differentially to a demultiplexer 614. The current to be injected at the multiplexer 608 is measured with the current sensor 614 and the current measurement is also passed to the demultiplexer 614, so that the microprocessor can query the measured current for the channel selected above and the measured associated voltage at the demultiplexer 614. The voltage is the sum of the individual voltages resulting from the injected superimposed sinusoidal currents. Both values are converted into a digital value by an analog-to-digital converter 616 and applied to a fast microcontroller interface of the microprocessor 602 as an input signal. The microprocessor 602 can now send the values to the battery control unit 104 and/or, if it is powerful enough, perform a Fourier analysis to obtain the impedance spectrum.

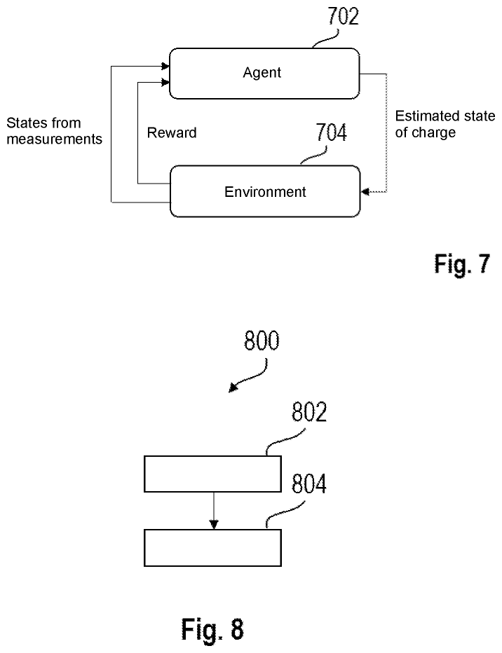

FIG. 7 shows a diagram of an artificial intelligence for estimating the state of charge and/or state of health of the battery cell units. One possible implementation of machine learning methods are so-called actuator/critic networks, which are implemented, for example, as Deep Deterministic Policy Grading (DDPG) methods. The training process on the cloud computer 102 for generating the individual SoC of a cell unit is explained here as an example.

The Cloud Computer 102 accesses several thousand characteristic data records from the past (e.g. from the last 6 months to the present). The Cloud Computer 102 creates a so-called “replay buffer” for this purpose. A feature data record consists of the time stamp, all measured impedance values of the recorded spectrum (typically within a few mHz and a few KHz), the average temperature of the battery cell unit, as well as a list of measured current and voltage values of the battery cell unit, e.g. over the past hour before the time stamp in question. Furthermore, the amount of charge transferred in ampere-seconds [As] can be obtained for the last time stamp by integrating the sampled current value over time (Coulomb counting). In relation to the nominal capacity of the battery cell units, a differential value of a recharged state of charge can be calculated as a percentage.

Note: In many BMS, the Coulomb counting method is used to determine the absolute SoC. However, this becomes increasingly inaccurate with increasing time due to the integration process, which cannot compensate for systematic measurement errors such as offsets.

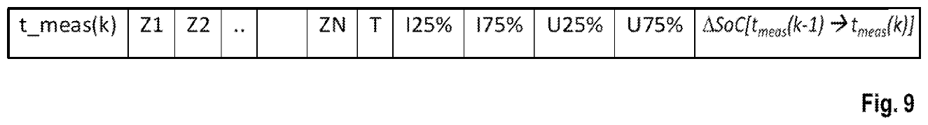

FIG. 9 shows a table with an example of a feature data set. Here mean:
t_meas(k): Timestamp of the kth recorded characteristic data record under consideration
Z1: First complex impedance value of the cell unit at the first measured frequency support point (magnitude and phase or real and imaginary part)
ZN: Last complex impedance value of the cell unit at the last measured frequency grid point (magnitude and phase or real and imaginary part)
T: Average temperature of the cell unit
I25%/U25%: Lower quartile of the measured current/voltage values from the immediate past at t_meas (k)
I75%/U75%: Upper quartile of the measured current/voltage values from the immediate past at t_meas (k)
ΔSoC[tₘₑₐₛ(k−1)→tₘₑₐₛ(k)]:
   Difference SoC to the previously recorded time stamp. This can be easily determined with the help of current integration over time (keyword: Coulomb counting, which is implemented in every BMS)

Such a characteristic data record is already created in the central battery control unit and transferred to the digital life file in the event of a wireless connection to the cloud computer.

In the learning process of an energy storage unit, the agent 702 continuously estimates the target variable (here the absolute SoC_{Est} [tₘₑₐₛ(k)] by not only using the arbitrarily selected kth characteristic data record from the replay buffer with the characteristic data records for estimation, but also by using other characteristic data records that are chronologically in the direct temporal past of the selected time stamp. As a rule, this direct temporal “proximity” is given for a number of feature datasets (e.g. M pieces) whose timestamps are 8-12 hours in the past to the selected timestamp. Within these time differences, a very preciseΔ SoC value is available as a difference value using the Coulomb counting method.

For all time stamps (i.e. from the selected kth and from the 8-12 hour past), agent 702 estimates the SoC as an absolute value based on the current agent model SoC_{Est} [tₘₑₐₛ(k)], SoC_{Est} [tₘₑₐₛ(k−1)], . . . , SoC_{Est} [tₘₑₐₛ(k−M)].

These estimation results can be used to determine a total reward value (see FIG. 7 “Reward”) for the estimated SoC_{Est} [tₘₑₐₛ(k)] in a model environment 704.

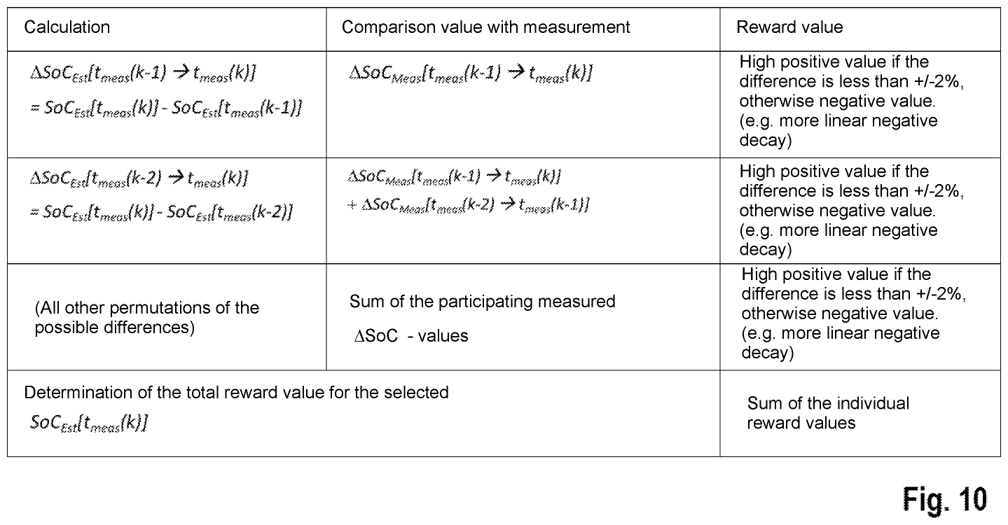

To evaluate the “estimation quality” of a selected feature data set as a reward value, a calculation rule as shown in FIG. 10 can now be used, for example.

The total forward value determined in this way is a suitable measure of the fact that the individual absolute estimated values SoC_{Est} [tₘₑₐₛ(k)], SoC_{Est} [tₘₑₐₛ(k−1)], . . . , SoC_{Est} [tₘₑₐₛ(k-M)] must in most cases match the actual, absolute but unknown SoC values for the available time stamps.

In addition, the machine learning process trains another critic network, not shown here, which is used to estimate the future cumulative total reward of the agent network. The critic network thus provides an estimate that can be used to evaluate the “generalized goodness” of the agent network.

FIG. 8 shows a flow diagram of a method 800 for providing a measurement data set of a battery cell unit in a cell string of a battery for determining a state of the battery cell unit, comprising the steps:

Acquisition 802 of measured variables of the battery cell unit during operation of the battery;

Providing 804 the recorded measured variables as measurement data for a battery control unit to determine a state of the battery cell unit.

In another embodiment of artificial intelligence, so-called recurrent (encoder/decoder) networks can be used. In a recurrent neural network, feedback between neurons of the same layer or previous layers is also possible.

In such a solution, the output layer of the neural network can be, for example, the estimated difference value of the current measurement time tₘₑₐₛ(k) to the previous measurement time tₘₑₐₛ(k−1)

$$Δ {SoC}_{Est} [ {t}_{meas} ( k ) ] = {SoC}_{Est} [ {t}_{meas} ( k ) ] \text{-} {SoC}_{Est} [ {t}_{meas} ( k - 1 ) ]$$

be. This is always available as an actual measured variable at the time tₘₑₐₛ(k−1).

The topology of the network can be selected in such a way that SoC_{Est} [tₘₑₐₛ(k)], SoC_{Est} [tₘₑₐₛ(k−1)] are present as the predecessor neuron layer (hidden neurons).

As already mentioned, the battery cell units can be cells connected in series and/or parallel and form a battery module when connected in series. A battery consists of several battery modules connected in series, which form a battery string. Several battery strings can be connected in parallel to increase the total capacity of the battery.

The following describes how the condition of the battery cell units in such battery modules and thus also the condition of the entire battery can be estimated, how a data basis for machine learning can be created during testing and how a battery module with one or more weak cells can be restored. The state is, for example, the state of health (SoH) as a ratio of the available capacity to the nominal capacity of the cells as well as an ageing-related parameter, e.g. the ageing-related relevant impedance, which is a measure of the available power

To create the data basis, learning can be divided into two phases:
an initial learning phase in which the status parameters of the battery cell units are measured directly. For example, the capacity (Ah) and the age-related impedance of each battery cell unit is measured directly for the first 500-800 battery modules. Although these measurements are relatively slow, as the battery modules have to be fully charged and discharged, they serve as a data basis for machine learning.

For example, limit values or ranges for capacities and ageing-related parameters can be defined, which classify the condition into quality classes. At the same time or within the test run, the various parameters mentioned above, such as impedance spectrum, temperature, etc., can be measured or determined and assigned to the ranges and fed to the machine learning algorithm as learning input variables and target variables. The machine learning algorithm thus learns the relationship between the measurement parameters and capacitance and ageing-related parameters so that no direct SoH determination needs to be carried out in the second phase.

In the second phase, the status, for example the SoH, is estimated indirectly using machine learning. This allows the state to be determined quickly.

This means that the battery measurement system can be used operationally for connected battery modules both in the first learning phase and in the second learning phase.

The process for creating the data basis for machine learning and assessing the condition of the cells in a first and second learning phase is explained below using two examples. In a first example, a battery with 12 battery modules, each with 8 battery cell units, is used to provide energy in a vehicle, for example a used electric car. The state of health SoH of the battery modules is unknown. The battery management system of the used electric car has no faults on the battery side. It can be assumed that the battery has equally good characteristics across all battery modules in terms of SoH and is functional for the operation of the electric car. At least two battery modules are initially selected.

If a sufficiently large training data set is not yet available as a measurement parameter for the battery cell type, the SoH must be recorded directly, as shown in the structure diagram 1200 in FIG. 12. During this measurement process, the relevant characteristic data records are stored as a parameter set in a central database 1214 as described above. If, for example, the battery modules are not among the first 500-800 modules since the start of the battery measurement system, the SoH of the 2×8 cells is measured directly in accordance with the first learning phase. To do this, the battery modules are first charged to 100% SoC in step 1202. The discharge process of the battery module is then started in step 1204. As long as the final discharge voltage has not been reached, step 1206, the relevant characteristics/parameters for the machine learning process are measured at selected states of charge in step 1208 and the current for recording the amount of charge transferred is integrated in step 1210. Parameters, e.g. for determining the impedance spectrum and other parameters as already described herein, are determined by measurements. After reaching the final discharge voltage, the current capacity in Ah and the relevant impedance (=SoH) are determined in step 1212. The direct measurements of the SoH of the two battery modules are used here to check the equally good properties. For example, the SoH of all cell units is 90%. The measurement data and results are then made available to the machine learning program. Only the direct SoH measurement is therefore used to assess the condition.

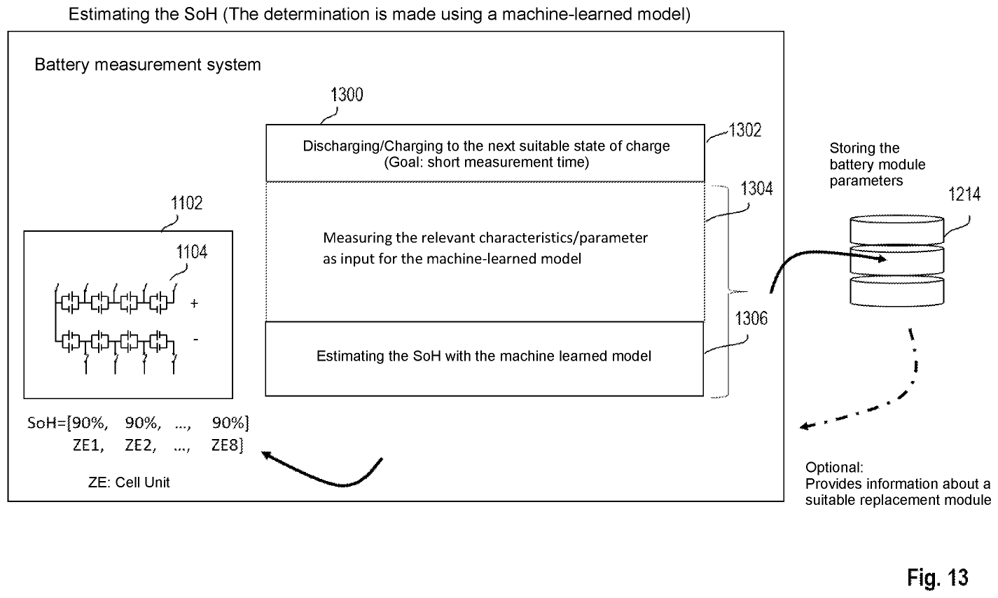

However, if the machine learning program has already been provided with measurement data and measurement results from 500-800 modules required for learning, the machine learning program is used to estimate the SoH in step 1306, as shown in the structure diagram 1300 of FIG. 13. For this purpose, direct measurement of the SoH is no longer necessary, but after discharging/charging to the next suitable state of charge with the aim of a short measurement time in step 1302, only measurements to determine the impedance spectrum and other parameters recorded at a selected operating point are required in step 1304.

In the first example, if a sufficient SoH value has been estimated or determined for all battery cell units, for example 90%, a quality certificate is issued and the modules can be used in the vehicle.

In a second example, the battery of the vehicle is defective. For example, a battery cell unit within a battery module is defective or at least in an unsatisfactory state of health. The state of health is determined in the same way as in the first example. If this shows, for example, that a battery cell unit has an SoH value of only 60%, while the remaining battery cell units have an SoH value of 90%, a request is triggered in the cloud, which responds with a selection of suitable used replacement modules with the same or at least a comparable quality as the intact battery cells of the module or battery cell units. As the battery measurement system records all measured battery modules in a central database, it is possible to identify a suitable replacement module from a created inventory.

The suitable used replacement module is balanced cell by cell before integration into the defective battery so that all battery cell units of the battery have the same voltage value. This means that the repaired battery is in a balanced state after the replacement module has been installed and can be used again immediately.

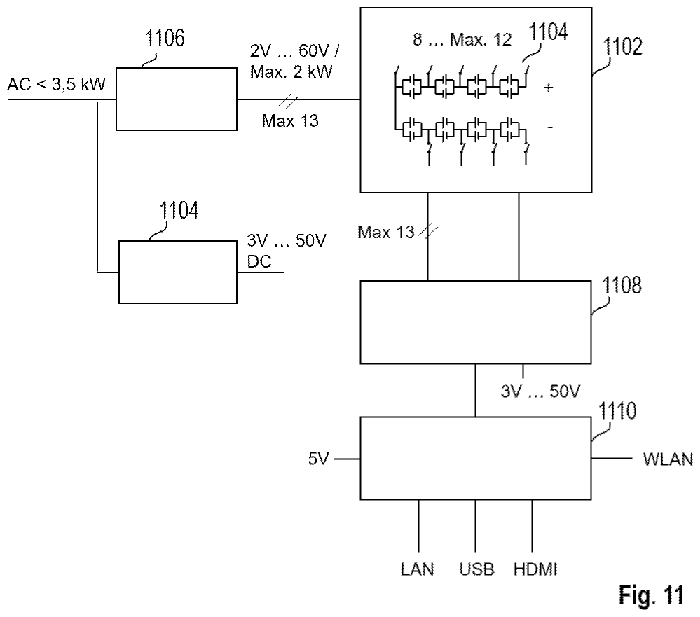

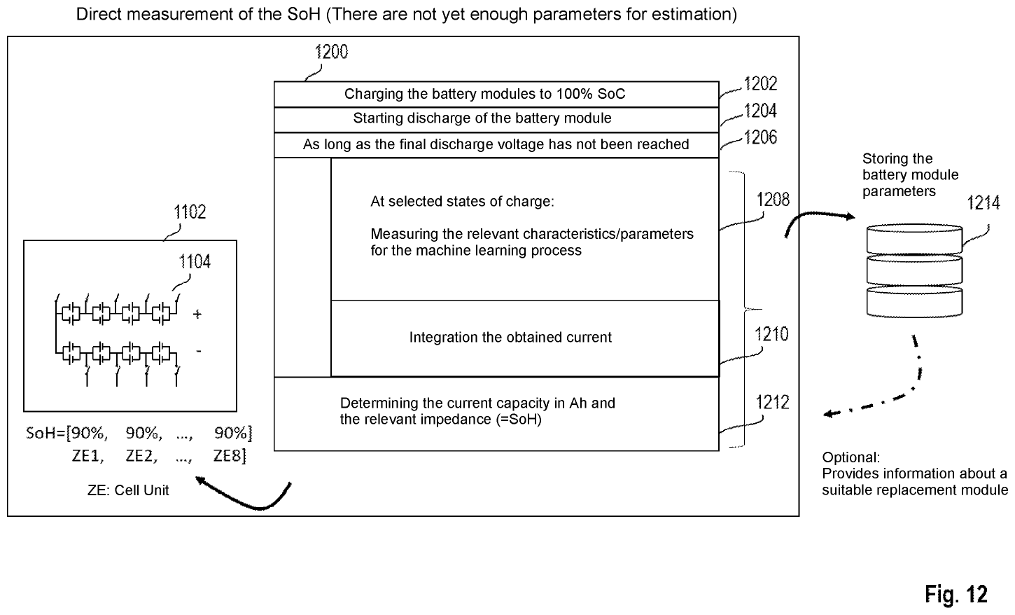

FIG. 11 shows a block diagram with an arrangement with which these tests can be carried out in the learning phases described. Block 1102 represents a battery module 1102 with several battery cell units 1104. The number of cell units 1104 here is eight, but may be more cells. Block 1106 represents, for example, the source/sink connected to the general AC power grid, which can supply up to 3.5 KW, for example. The source/sink 1106, which corresponds, for example, to the source/sink 331 in FIG. 3, converts the AC mains voltages into 2V to 60V or vice versa and thus allows selective charging/discharging of the entire battery module 1102 or also of an individual battery cell unit 1104. In addition, further voltage sources may be available for the internal voltage supply of the battery measurement system. Block 1108 represents, for example, the measuring unit 213 from FIG. 2 or the measuring unit shown in FIG. 6, which is connected to the battery module 1102 via a bus with, for example, 13 lines-corresponding to the number of battery cell units 1104. Block 1110 represents, for example, a processing unit with the microprocessor 602 shown in FIG. 6. The processing unit 1110 also has LAN, WLAN, USB and HDMI interfaces. The battery or at least the modules 1102, which are subjected to the test, can be placed in a thermal chamber so that they can be tested under defined and different temperatures. The impedance spectrum is determined with this arrangement, as already described in detail herein. The LAN or WLAN connections are used, for example, to transfer the measured parameters to a memory and to the machine learning program, to communicate with a control PC, to receive the diagnostic model and to select the replacement modules. Furthermore, a web server can also be provided via the WLAN/LAN connection as a user interface for controlling the battery measurement system and displaying the relevant data. Alternatively, an HDMI interface is also available for connecting a display. Input devices, external memories and other devices known to the specialist can be connected to the USB interface.

1. A battery cell measuring unit, wherein the measuring unit is configured to detect measured variables of a battery cell unit in a cell string with a plurality of battery cell units of a battery,
wherein the measuring unit is furthermore configured to detect measured variables for determining a state of the battery cell unit during operation of the battery and to provide the determined measured variables as a set of measurement data to a battery control unit;
wherein the measuring unit is configured to detect the measured variables for determining a state of the battery cell unit and to provide the determined measured variables as a measurement data set to a battery control unit only when the cell string is disconnected from other cell strings of the battery during operation of the battery.

2. The battery cell measuring unit according to claim 1, wherein the measuring unit is furthermore configured to detect the following measured variables:
an alternating current of different frequencies injected into the battery cell unit as an excitation for determining an impedance spectrum; and
a voltage and a phase relative to the injected alternating current as a voltage response for a determination of the impedance spectrum; wherein
the measuring unit is furthermore configured to provide values of the measured variables and/or values of the impedance spectrum with a time stamp and to make them available to the battery control unit as a measurement data set.

3. The battery cell measuring unit according to claim 1, wherein the measuring unit is furthermore configured to additionally detect one or more of the following measured variables: temperature, pressure in the battery cell unit, chemical and physical parameters.

4. A measuring unit arrangement comprising a plurality of measuring units according to claim 1 for a plurality of battery cell units in the battery,
wherein the battery has a DC bus connection with a plurality of cell strings arranged in parallel thereon, each with one or more battery cell units connected in series;
wherein at least some of the cell strings each have one or more measuring units which each detect measured variables of a battery cell unit, wherein the one or more measuring units of a cell string are configured to simultaneously detect measured variables of a battery cell unit in the cell string and to organize the detected measured variables for provision to the battery control unit as a measurement data set.

5. A battery measurement system, comprising:
a measuring unit arrangement according to the preceding claim, comprising a plurality of measuring units arranged in at least one cell string;
a battery control unit; and
a current source for each measuring unit, which can also work as a sink;
wherein each of the measuring units is associated with at least one battery cell unit and each of the measuring units is configured to send measurement data sets to the battery control unit;
the battery control unit is configured to receive measurement data sets from measurement units of at least one cell string; and
the current sources are each configured to inject a current at a frequency into the battery cell unit of the associated measuring unit.

6. The battery measurement system according to claim 5, wherein each cell string has a switch or a switchable converter for isolating the cell string from the other cell strings, wherein only those measurement units are configured to provide measurement variables and measurement data sets which are assigned to this cell string.

7. The battery measurement system according to claim 5, wherein the battery control unit is configured to generate a respective characteristic data set from the measurement data sets of the measurement units, to apply a time stamp to the characteristic data set and to temporarily store the characteristic data set including the time stamp.

8. The battery measurement system according to claim 5, further comprising a computing unit and a communication interface, which are configured to transmit the temporarily stored feature data records to the computing unit, wherein the computing unit is configured to receive the temporarily stored feature data records and to cyclically calculate a model of a machine learning system, wherein the model provides diagnostic functions and/or a battery status for each measuring unit on the basis of current feature data records, and the computing unit is furthermore configured to transmit the model via the communication interface to the battery control unit.

9. The battery measurement system according to claim 6, wherein the battery measurement system is configured to disconnect the disconnected cell string for a short time for measurement while the other cell strings continue to operate according to a regular operation of the battery.

10. The battery measurement system according to claim 5, further comprising;
sensors that are configured to detect other environmental variables, and
a local memory configured to store the feature data records and the other measured environmental variables recorded.

11. The battery measurement system according to claim 8, wherein the model is an artificial intelligence model that is configured to generate a diagnostic model from the feature data sets using the time stamps, respectively.

12. The battery measurement system according to claim 8, wherein the model is a model according to a recurrent neural network method, a reinforcement learning method and/or an actor/critic method, wherein the reinforcement learning method uses a reward for learning within an environment model.

13. The battery measurement system according to claim 8, wherein the model is an artificial intelligence model further configured to estimate a state of charge state value, a state of health state value, a state value with respect to a temperature, a chemical and/or a physical property.

14. A method for providing a measurement data set of a battery cell unit in a cell string of a battery for a determination of a state of the battery cell unit, comprising the steps of:
separating the cell string for the measurement;
acquiring measured variables of the battery cell unit during operation of the battery; and
provisioning the acquired measured variables as measurement data for a battery control unit for determining a state of the battery cell unit by a previously trained artificial intelligence model;
so that the measured variables for determining a state of the battery cell unit are detected and the determined measured variables are only provided as a measurement data set of a battery control unit only when the cell string is disconnected from other cell strings of the battery during operation of the battery.

15. Use of a battery measurement system according to claim 5 in an electrically powered means of transportation or a stationary storage of electrical energy.

16. Electrically powered means of transportation or stationary storage of electrical energy, comprising a battery measurement system according to claim 5.
